(19) United States
(12) Patent Application Publication
(10) Pub. No.: US 2025/0203908 A1
(43) Pub. Date: Jun. 19, 2025

(54) SEMICONDUCTOR POWER DEVICE

(71) Applicant: National Tsing Hua University, Hsinchu City (TW)

(72) Inventors: King Yuen Wong, Hsinchu City (TW); Chao-Hui Yeh, Yunlin County (TW); Shuo-Hung Hsu, Hsinchu City (TW)

(73) Assignee: National Tsing Hua University, Hsinchu City (TW)

(21) Appl. No.: 18/607,533

(22) Filed: Mar. 17, 2024

(30) Foreign Application Priority Data
Dec. 18, 2023 (TW) 112149308

(51) Int. Cl. H01L 29/778; H01L 27/06; H01L 29/20

(52) U.S. Cl. CPC H10D 30/475; H10D 62/8503; H10D 84/40

(57) ABSTRACT

Provided is a semiconductor power device including a substrate having a circuit region and a power device region, a buffer layer, a nitride channel layer, a barrier layer, a power transistor and a complementary logic circuit. The buffer layer is disposed on the substrate. The nitride channel layer is disposed on the buffer layer. The barrier layer is disposed on the nitride channel layer. The power transistor is disposed on the substrate in the power device region. The complementary logic circuit is disposed on the substrate in the circuit region and electrically connected to the power transistor, and includes a P-type transistor and an N-type transistor. The P-type transistor includes a 2D material channel layer. The N-type transistor is electrically connected to the P-type transistor. A 2DEG is located in the nitride channel layer and adjacent to an interface between the nitride channel layer and the barrier layer.

### CROSS-REFERENCE TO RELATED APPLICATION

This application claims the priority benefit of Taiwan application serial no. 112149308, filed on Dec. 18, 2023. The entirety of the above-mentioned patent application is hereby incorporated by reference herein and made a part of this specification.

### BACKGROUND

### Technical Field

The disclosure relates to a semiconductor device, and in particular to a semiconductor power device.

### Description of Related Art

In recent years, in response to the demand for high-frequency semiconductor apparatus, the semiconductor power devices have developed into Group III-V semiconductor power devices, such as AlGaN—GaN HEMT devices. Generally speaking, the AlGaN—GaN HEMT device is a transistor with high electron mobility using a AlGaN layer as the Schottky barrier layer. In the AlGaN—GaN HEMT device, the interface between the AlGaN layer as the barrier layer and the GaN layer as the channel layer may form a two-dimensional electron gas (2DEG) in the AlGaN layer below the interface due to spontaneous polarization and piezoelectric polarization effects. The Group III-V semiconductor material is suitable for high-frequency applications through factors such as the high electron mobility, the high concentration of electrons possessed by the 2DEG, and the low sheet resistance value of GaN.

For the current semiconductor power device, it may include a power transistor and a logic integrated circuit electrically connected to the power transistor. Therefore, how to integrate a high-performance complementary logic circuit into a semiconductor power device is an important issue.

### SUMMARY

The disclosure provides a semiconductor power device, which includes a power transistor and a complementary logic circuit including two-dimensional (2D) material.

The semiconductor power device of the disclosure includes a substrate, a buffer layer, a nitride channel layer, a barrier layer, a power transistor and a complementary logic circuit. The substrate has a circuit region and a power device region. The buffer layer is disposed on the substrate. The nitride channel layer is disposed on the buffer layer. The barrier layer is disposed on the nitride channel layer. The power transistor is disposed on the substrate in the power device region. The complementary logic circuit is disposed on the substrate in the circuit region and electrically connected to the power transistor, and includes a P-type transistor comprising a two-dimensional (2D) material channel layer and an N-type transistor electrically connected to the P-type transistor. A two-dimensional electron gas (2DEG) is located in the nitride channel layer and adjacent to an interface between the nitride channel layer and the barrier layer.

In an embodiment of the semiconductor power device of the disclosure, the 2DEG is located only in the power device region.

In an embodiment of the semiconductor power device of the disclosure, the 2DEG is located below a gate, a source and a drain of the power transistor.

In an embodiment of the semiconductor power device of the disclosure, each of the P-type transistor and the N-type transistor includes a gate disposed on the barrier layer, a dielectric layer disposed between the gate and the barrier layer, a channel layer disposed on the gate, a gate dielectric layer disposed between the gate and the channel layer, and a source and a drain disposed on the channel layer, wherein the channel layer is the 2D material channel layer.

In an embodiment of the semiconductor power device of the disclosure, each of the P-type transistor and the N-type transistor includes a channel layer disposed on the barrier layer, a dielectric layer disposed between the channel layer and the barrier layer, a gate, a source and a drain disposed on the channel layer, and a gate dielectric layer disposed between the gate and the channel layer, wherein the channel layer is the 2D material channel layer.

In an embodiment of the semiconductor power device of the disclosure, the 2DEG is not located below a gate of the power transistor.

In an embodiment of the semiconductor power device of the disclosure, each of the P-type transistor and the N-type transistor includes a gate disposed on the barrier layer, a dielectric layer disposed between the gate and the barrier layer, a channel layer disposed on the gate, a gate dielectric layer disposed between the gate and the channel layer, and a source and a drain disposed on the channel layer, wherein the channel layer of the P-type transistor is the 2D material channel layer, and the channel layer of the N-type transistor is not the 2D material channel layer.

In an embodiment of the semiconductor power device of the disclosure, each of the P-type transistor and the N-type transistor includes a channel layer disposed on the barrier layer, a dielectric layer disposed between the channel layer and the barrier layer, a gate, a source and a drain disposed on the channel layer, and a gate dielectric layer disposed between the gate and the channel layer, wherein the channel layer of the P-type transistor is the 2D material channel layer, and the channel layer of the N-type transistor is not the 2D material channel layer.

In an embodiment of the semiconductor power device of the disclosure, the 2DEG is located in the power device region and the circuit region.

In an embodiment of the semiconductor power device of the disclosure, the 2DEG is located below a gate, a source and a drain of the power transistor.

In an embodiment of the semiconductor power device of the disclosure, each of the P-type transistor and the N-type transistor includes a gate penetrating through the barrier layer, disposed on the nitride channel layer and in contact with the 2DEG, a channel layer disposed on the barrier layer, a dielectric layer disposed between the channel layer and the barrier layer, and a source and a drain, disposed on the channel layer, wherein the channel layer is the 2D material channel layer, and the 2DEG is located below the gates, the sources and the drains of the P-type transistor and the N-type transistor.

In an embodiment of the semiconductor power device of the disclosure, the 2DEG is not located below a gate of the power transistor.

In an embodiment of the semiconductor power device of the disclosure, each of the P-type transistor and the N-type transistor includes a gate penetrating through the barrier layer, disposed on the nitride channel layer and in contact with the 2DEG, a channel layer disposed on the barrier layer, a dielectric layer disposed between the channel layer and the barrier layer, and a source and a drain disposed on the channel layer, wherein the channel layer of the P-type transistor is the 2D material channel layer, the channel layer of the N-type transistor is not the 2D material channel layer, and the 2DEG is located below the gates, the sources and the drains of the P-type transistor and the N-type transistor.

In an embodiment of the semiconductor power device of the disclosure, a material of the 2D material channel layer comprises graphene, silicene, boron nitride nanosheet (BNNS), transition metal dichalcogenide (TMDC), phosphorene, metal oxide nanosheet or Group II-VI compound.

The semiconductor power device of the disclosure includes a substrate, an undoped buffer layer, an undoped spacer layer, a power transistor and a complementary logic circuit. The substrate has a circuit region and a power device region. The undoped buffer layer is disposed on the substrate. The undoped spacer layer is disposed on the undoped buffer layer. The power transistor is disposed on the substrate in the power device region. The complementary logic circuit is disposed on the substrate in the circuit region and electrically connected to the power transistor, and includes a P-type transistor including a 2D material channel layer and an N-type transistor electrically connected to the P-type transistor. A 2DEG is located in the undoped buffer layer in the power device region and adjacent to an interface between the undoped buffer layer and the undoped spacer layer.

In an embodiment of the semiconductor power device of the disclosure, the 2DEG is located below a gate, a source and a drain of the power transistor.

In an embodiment of the semiconductor power device of the disclosure, each of the P-type transistor and the N-type transistor includes a gate disposed on the undoped spacer layer, a dielectric layer disposed between the gate and the undoped spacer layer, a channel layer disposed on the gate, a gate dielectric layer disposed between the gate and the channel layer, and a source and a drain disposed on the channel layer, wherein the channel layer is the 2D material channel layer.

In an embodiment of the semiconductor power device of the disclosure, the 2DEG is not located below a gate of the power transistor.

In an embodiment of the semiconductor power device of the disclosure, each of the P-type transistor and the N-type transistor includes a gate disposed on the undoped spacer layer, a dielectric layer disposed between the gate and the undoped spacer layer, a channel layer disposed on the gate, a gate dielectric layer disposed between the gate and the channel layer, and a source and a drain disposed on the channel layer, wherein the channel layer of the P-type transistor is the 2D material channel layer, and the channel layer of the N-type transistor is not the 2D material channel layer.

In an embodiment of the semiconductor power device of the disclosure, a material of the 2D material channel layer comprises graphene, silicene, BNNS, TMDC, phosphorene, metal oxide nanosheet or Group II-VI compound.

Based on the above, the semiconductor power device of the disclosure includes a power transistor and a complementary logic circuit including 2D material electrically connected to the power transistor. Therefore, a logic circuit with low power dissipation and high-speed operating frequency may be realized, and the semiconductor power device has high electron mobility and high output current.

### BRIEF DESCRIPTION OF THE DRAWINGS

FIG. 1A is a schematic cross-sectional view of a semiconductor power device according to the first embodiment of the disclosure.

FIG. 1B is a circuit diagram of the semiconductor power device according to the first embodiment of the disclosure.

FIG. 2 is a schematic cross-sectional view of a semiconductor power device according to the second embodiment of the disclosure.

FIG. 3 is a schematic cross-sectional view of a semiconductor power device according to the third embodiment of the disclosure.

FIG. 4 is a schematic cross-sectional view of a semiconductor power device according to the fourth embodiment of the disclosure.

FIG. 5 is a schematic cross-sectional view of a semiconductor power device according to the fifth embodiment of the disclosure.

FIG. 6 is a schematic cross-sectional view of a semiconductor power device according to the sixth embodiment of the disclosure.

FIG. 7 is a schematic cross-sectional view of a semiconductor power device according to the seventh embodiment of the disclosure.

FIG. 8 is a schematic cross-sectional view of a semiconductor power device according to the eighth embodiment of the disclosure.

FIG. 9 is a schematic cross-sectional view of a semiconductor power device according to the ninth embodiment of the disclosure.

FIG. 10 is a schematic cross-sectional view of the semiconductor power device according to the tenth embodiment of the disclosure.

FIG. 11 is a schematic cross-sectional view of the semiconductor power device according to the eleventh embodiment of the disclosure.

### DESCRIPTION OF THE EMBODIMENTS

The embodiments are listed below and described in detail with the accompanying drawings, but the provided embodiments are not intended to limit the scope of the disclosure. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the disclosure.

In addition, the directional terms, such as “on”, “above”, “under” and “below” mentioned in the text are only used to refer to the direction of the drawings, and are not used to limit the disclosure.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

The semiconductor power device of the embodiment of the disclosure includes a power transistor and a complementary logic circuit electrically connected to the power transistor, and the transistor in the complementary logic circuit includes the 2D material channel layer. Therefore, the complementary logic circuit in the semiconductor power device of the embodiment of the disclosure may have low power dissipation and high-speed operating frequency, and the semiconductor power device of the embodiment of the disclosure may have high electron mobility and high output current.

In each of the following embodiments, a high-electron-mobility transistor (HEMT) is used as an example of the power transistor for explanation, but the disclosure is not limited thereto. In other embodiments, the power transistor may be other types of transistors, such as a heterojunction bipolar transistor (HBT). The semiconductor power device of the embodiment of the disclosure will be described in detail below.

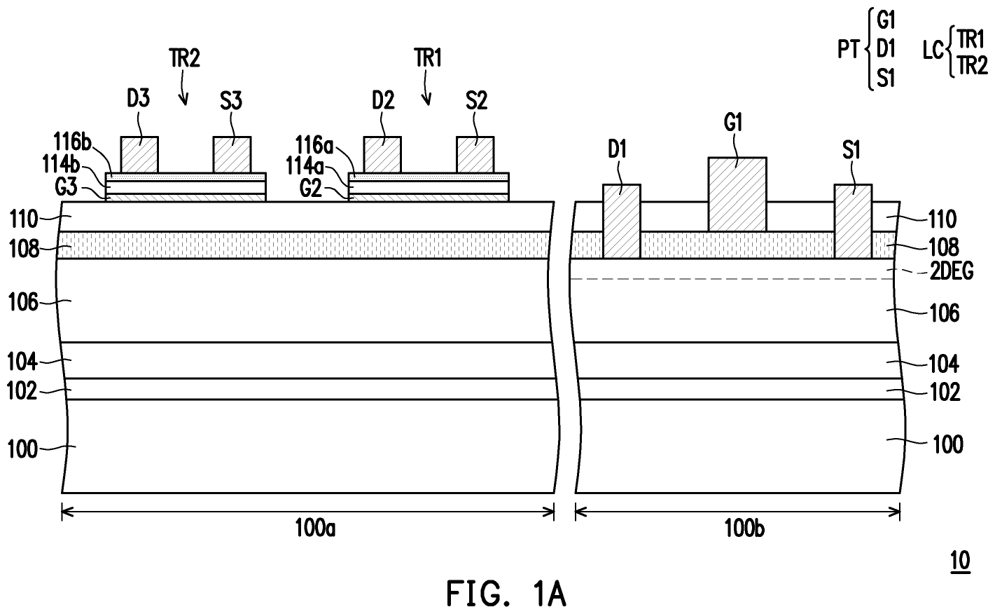

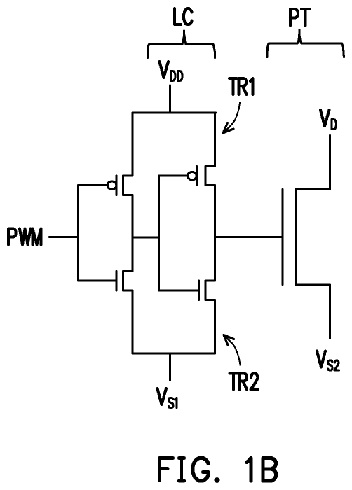

FIG. 1A is a schematic cross-sectional view of a semiconductor power device according to the first embodiment of the disclosure.

Referring to FIG. 1A, the semiconductor power device 10 includes the substrate 100, the nucleation layer 102, the buffer layer 104, the nitride channel layer 106, the barrier layer 108, the power transistor PT and the complementary logic circuit LC.

In the present embodiment, the substrate 100 has a circuit region 100a and a power device region 100b. The substrate 100 is, for example, a silicon (Si) substrate, a silicon carbide (SiC) substrate, a gallium nitride (GaN) substrate, a gallium arsenide (GaAs) substrate, an indium phosphide (InP) substrate or a sapphire substrate. The nucleation layer 102 is disposed on the substrate 100. The material of the nucleation layer 102 is, for example, AlN, GaN or AlGaN. The thickness of the nucleation layer 102 is, for example, between 5 nm and 50 nm.

The buffer layer 104 is disposed on the nucleation layer 102. The material of the buffer layer 104 is, for example, GaN. The thickness of the buffer layer 104 is, for example, between 0.5 μm and 6 μm. The nitride channel layer 106 is disposed on the buffer layer 104. The material of the nitride channel layer 106 is, for example, GaN or InGaN. The thickness of the nitride channel layer 106 is, for example, between 0.2 μm and 0.8 μm. The barrier layer 108 is disposed on the nitride channel layer 106. The material of the barrier layer 108 is, for example, AlGaN, AlInN, AlN or AlGaInN. The thickness of the barrier layer 108 is, for example, between 5 nm and 30 nm.

The 2DEG is located in the nitride channel layer 106, which is adjacent to the interface between the nitride channel layer 106 and the barrier layer 108. In the present embodiment, the 2DEG is only located in the power device region 100b. In other words, there is no 2DEG in the nitride channel layer 106 in the circuit region 100a.

In addition, in the present embodiment, the dielectric layer 110 is disposed on the barrier layer 108. The material of the dielectric layer 110 is, for example, nitride, such as silicon nitride, or silicon oxide. The thickness of the dielectric layer 110 is, for example, between 1 nm and 150 nm. The dielectric layer 110 may be used as a passivation layer.

The power transistor PT is disposed on the substrate 100 in the power device region 100b. In detail, in the present embodiment, the power transistor PT includes a gate G1, a source S1 and a drain D1. The gate G1 penetrates through the dielectric layer 110 and is disposed on the barrier layer 108. The source S1 and the drain D1 are located at both sides of the gate G1, respectively. The source S1 and the drain D1 respectively penetrate through the dielectric layer 110 and the barrier layer 108 and are disposed on the nitride channel layer 106 and contact the 2DEG. In this way, in the present embodiment, the 2DEG is located below the gate G1, the source S1 and the drain S1. That is, in the present embodiment, the power transistor PT is a depletion-mode (D-mode) power transistor. The material of the gate G1 is, for example, TiN, Ni, Au, Pt or a combination thereof. The material of the source S1 and the drain D1 is, for example, Ti, Al, TiN, Ni, Au or a combination thereof.

The complementary logic circuit LC is disposed on the substrate 100 in the circuit region 100a, and is electrically connected to the power transistor PT. In the present embodiment, complementary logic circuit LC includes a P-type transistor TR1 and an N-type transistor TR2 electrically connected to the P-type transistor TR1.

In addition, in the present embodiment, since the power transistor PT is a D-mode power transistor, the P-type transistor TR1 and the N-type transistor TR2 in the complementary logic circuit LC each include a 2D material channel layer. The material of the 2D material channel layer is, for example, graphene, silicene, BNNS, TMDC, phosphorene, metal oxide nanosheet or group II-VI compound. Depending on the conductivity type of the transistor, such P type or N type, the 2D material used for the 2D material channel layer may be different, which is well known to those skilled in the art and will not be explained here.

In detail, in the present embodiment, the P-type transistor TR1 includes the gate G2 disposed on the dielectric layer 110, the channel layer 116a disposed on the gate G2, the gate dielectric layer 114a disposed between the gate G2 and the channel layer 116a, and the source S2 and the drain D2 disposed on the channel layer 116a, and the N-type transistor TR2 includes the gate G3 disposed on the dielectric layer 110, the channel layer 116b disposed on the gate G3, the gate dielectric layer 114b disposed between the gate G3 and the channel layer 116b, and the source S3 and the drain D3 disposed on the channel layer 116b.

The channel layer 116a and the channel layer 116b are both 2D material channel layers. The material of the gate dielectric layer 114a and the gate dielectric layer 114b is, for example, silicon nitride, silicon oxide, HfO₂, Al2O₃ or a combination thereof. The thickness of the gate dielectric layer 114a and the gate dielectric layer 114b is, for example, between 0.1 nm and 10 nm. The material of the gate G2 and the gate G3 is, for example, Ni, Au, Pt or a combination thereof. The material of the source S2, the drain D2, the source S3 and the drain D3 is, for example, Ni, Au, In, Pt, Pd, Sc or a combination thereof.

The circuit diagram corresponding to the semiconductor power device 10 is shown in FIG. 1B. The complementary logic circuit LC is electrically connected to the power transistor PT, and the complementary logic circuit LC is connected to the inverter connected to the pulse width modulation circuit PWM. The source S2 of the P-type transistor TR1 of the complementary logic circuit LC is connected to the voltage source VDD, the drain D3 of the N-type transistor TR2 of the complementary logic circuit LC is connected to the voltage source Vs1, the source S1 of the power transistor PT is connected to the voltage source Vs2, and the drain D1 of the power transistor PT is connected to the voltage source VD. The circuit diagram in FIG. 1B is only exemplary, and the disclosure is not limited thereto.

In the semiconductor power device 10, the power transistor PT is a D-mode power transistor, the complementary logic circuit LC is electrically connected to the power transistor PT, and the channel layer of the P-type transistor TR1 and the channel layer of the N-type transistor TR2 in the complementary logic circuit LC are both the 2D material channel layers. Therefore, the complementary logic circuit LC may have low power dissipation and high-speed operating frequency, and the semiconductor power device 10 may have high electron mobility and high output current.

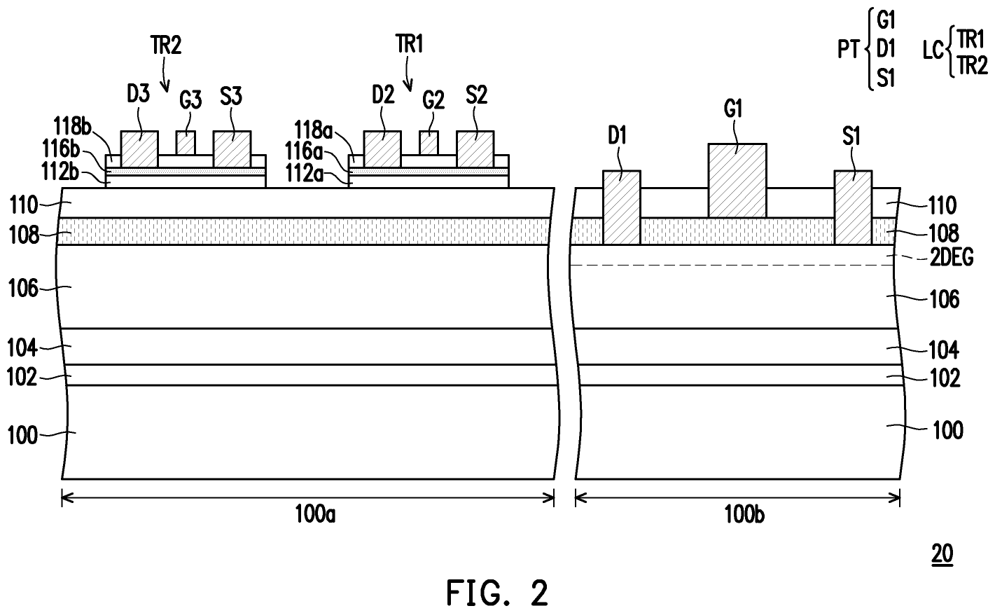

FIG. 2 is a schematic cross-sectional view of a semiconductor power device according to the second embodiment of the disclosure. In the present embodiment, elements that are the same as those in the first embodiment will be represented by the same reference symbols and will not be described again.

Referring to FIG. 2, the difference between the semiconductor power device 20 of the present embodiment and the semiconductor power device 10 is that in the semiconductor power device 20, the P-type transistor TR1 includes the channel layer 116a disposed on the dielectric layer 110, the dielectric layer 112a disposed between the channel layer 116a and the dielectric layer 110, the gate G2, the source S2 and the drain D2 disposed on the channel layer 116a, and the gate dielectric layer 118a disposed between the gate G2 and the channel layer 116a, and the N-type transistor TR2 includes the channel layer 116b disposed on the dielectric layer 110, the dielectric layer 112b disposed between channel layer 116b and the dielectric layer 110, the gate G3, the source S3 and the drain D3 disposed on the channel layer 116b, and the gate dielectric layer 118b disposed between the gate G3 and the channel layer 116b.

The material of the gate dielectric layer 118a and the gate dielectric layer 118b is, for example, silicon nitride, silicon oxide, HfO₂, Al2O₃ or a combination thereof. The thickness of the gate dielectric layer 118a and the gate dielectric layer 118b is, for example, between 0.1 nm and 10 nm. In addition, the material of the dielectric layer 112a and the dielectric layer 112b is, for example, silicon nitride, silicon oxide, HfO₂, Al2O₃ or a combination thereof.

In the semiconductor power device 20, the power transistor PT is a D-mode power transistor, the complementary logic circuit LC is electrically connected to the power transistor PT, and the channel layer of the P-type transistor TR1 and the channel layer of the N-type transistor TR2 in the complementary logic circuit LC are both the 2D material channel layers. Therefore, the complementary logic circuit LC may have low power dissipation and high-speed operating frequency, and the semiconductor power device 20 may have high electron mobility and high output current.

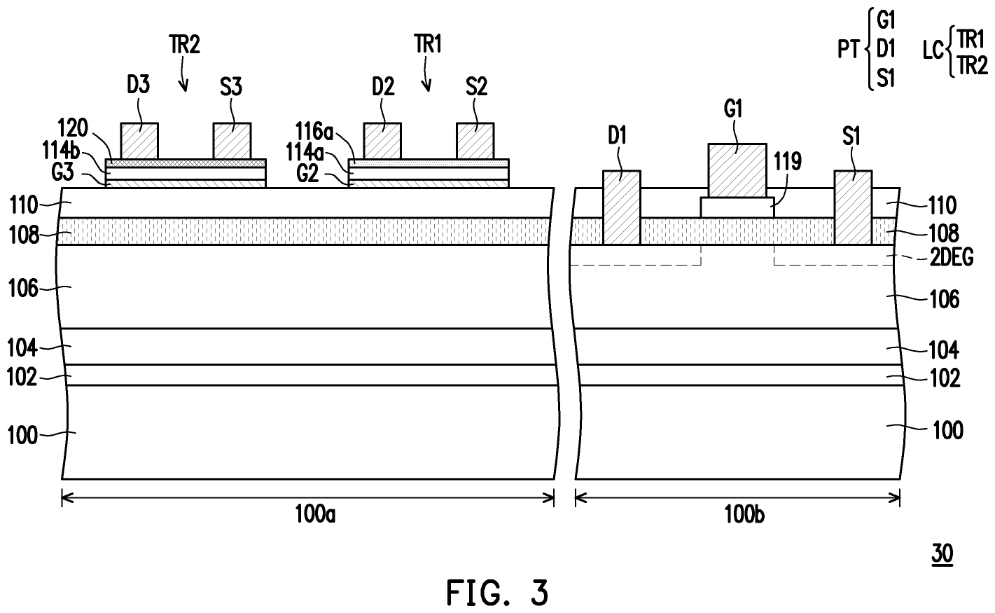

FIG. 3 is a schematic cross-sectional view of a semiconductor power device according to the third embodiment of the disclosure. In the present embodiment, elements that are the same as those in the first embodiment will be represented by the same reference symbols and will not be described again.

Referring to FIG. 3, the difference between the semiconductor power device 30 of the present embodiment and the semiconductor power device 10 is that in the semiconductor power device 30, there is no 2DEG below the gate G1 of the power transistor PT and the doped GaN layer is disposed between the gate G1 and the barrier layer 108. That is, in the present embodiment, the power transistor PT is an enhancement mode (E-mode) power transistor.

In the present embodiment, since the power transistor PT is an E-mode power transistor, in the complementary logic circuit LC, the P-type transistor TR1 includes the 2D material channel layer, while the N-type transistor TR2 does not include the 2D material channel layer. That is, the channel layer 116a of P-type transistor TR1 is the 2D material channel layer, while the channel layer 120 of N-type transistor TR1 is not the 2D material channel layer. The material of the channel layer 120 of the N-type transistor TR1 is, for example, GaN.

In the semiconductor power device 30, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 30 may have high electron mobility and high output current.

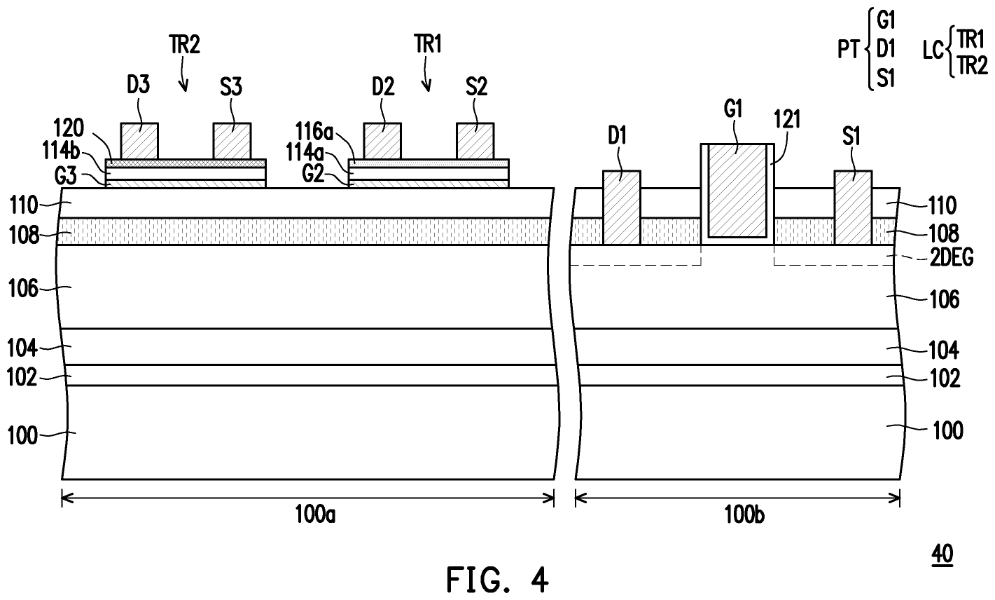

FIG. 4 is a schematic cross-sectional view of a semiconductor power device according to the fourth embodiment of the disclosure. In the present embodiment, elements that are the same as those in the third embodiment will be represented by the same reference symbols and will not be described again.

Referring to FIG. 4, the difference between the semiconductor power device 40 of the present embodiment and the semiconductor power device 30 is that in the semiconductor power device 40, the bottom of the gate G1 of the power transistor PT is located in the barrier layer 108, and the sidewalls and the bottom of the gate G1 are surrounded by the dielectric layer 121. The material of the dielectric layer 121 is, for example, a high-dielectric-constant (high-k) material. In the text, the high-k material refers to a dielectric material with a dielectric constant greater than 4, which is well known to those skilled in the art.

In the semiconductor power device 40, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 40 may have high electron mobility and high output current.

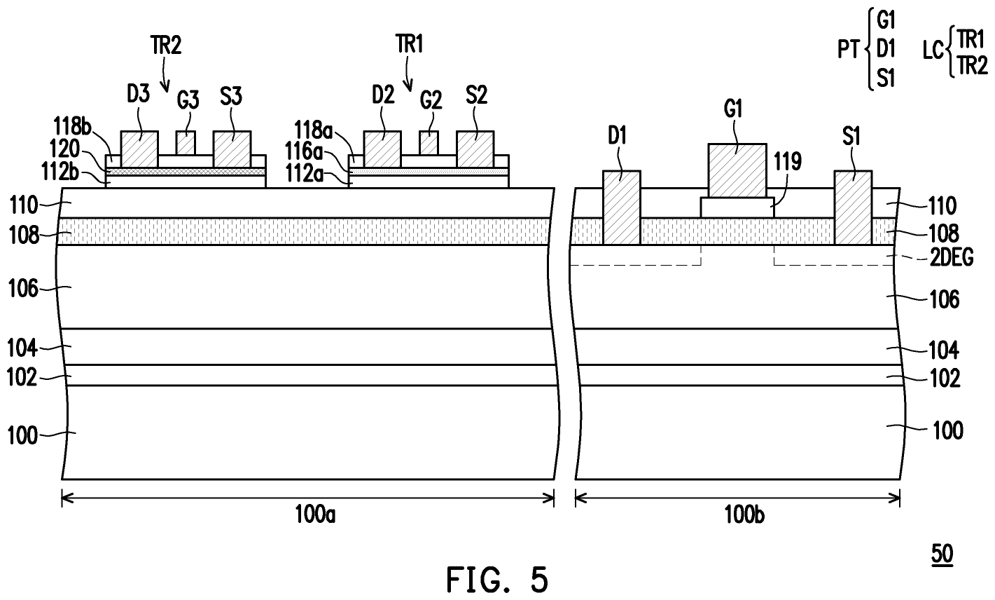

FIG. 5 is a schematic cross-sectional view of a semiconductor power device according to the fifth embodiment of the disclosure. In the present embodiment, elements that are the same as those in the third embodiment will be represented by the same reference symbols and will not be described again.

Referring to FIG. 5, the difference between the semiconductor power device 50 of the present embodiment and the semiconductor power device 30 is that in the semiconductor power device 50, the complementary logic circuit LC has a similar configuration to the complementary logic circuit LC of the semiconductor power device 20, wherein the channel layer of N-type transistor TR1 is channel layer 120. That is, the channel layer of N-type transistor TR1 is not the 2D material channel layer.

In the semiconductor power device 50, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 50 may have high electron mobility and high output current.

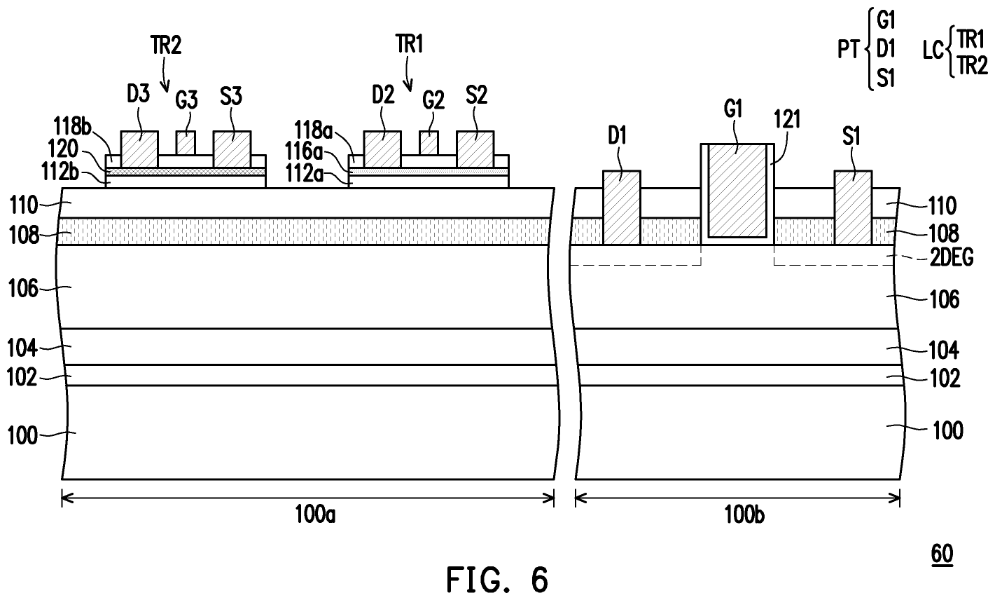

FIG. 6 is a schematic cross-sectional view of a semiconductor power device according to the sixth embodiment of the disclosure. In the present embodiment, elements that are the same as those in the fifth embodiment will be represented by the same reference symbols and will not be described again.

Referring to FIG. 6, the difference between the semiconductor power device 60 of the present embodiment and the semiconductor power device 50 is that in the semiconductor power device 60, the power transistor PT has the same configuration as the power transistor PT of the semiconductor power device 40.

In the semiconductor power device 60, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 60 may have high electron mobility and high output current.

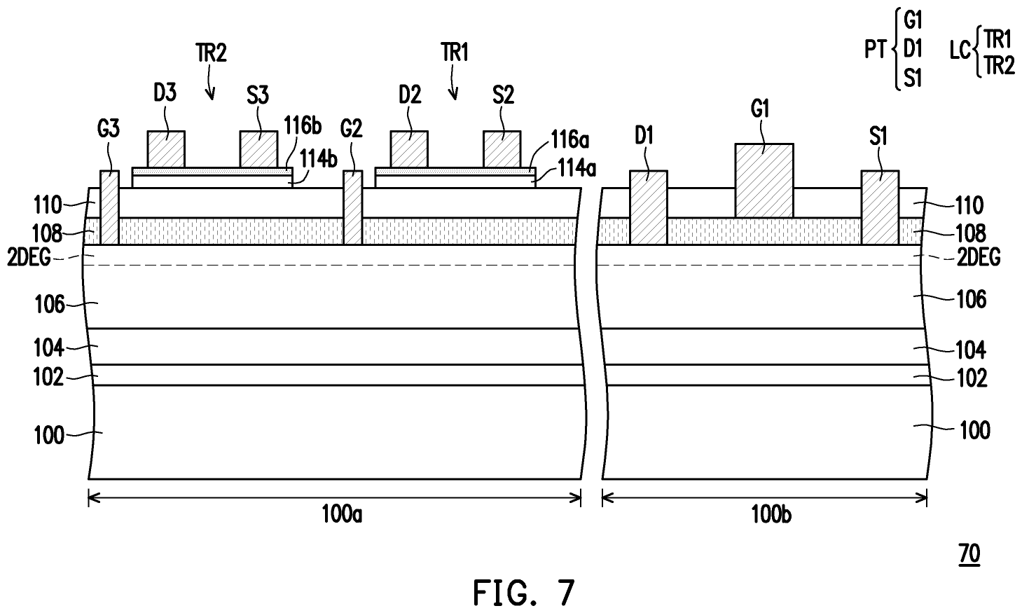

FIG. 7 is a schematic cross-sectional view of a semiconductor power device according to the seventh embodiment of the disclosure. In the present embodiment, elements that are the same as those in the first embodiment will be represented by the same reference symbols and will not be described again.

Referring to FIG. 7, the difference between the semiconductor power device 70 of the present embodiment and the semiconductor power device 10 is that in the semiconductor power device 70, the 2DEG is not only located in the power device region 100b, but also in the circuit region 100a.

In addition, the P-type transistor TR1 includes the gate G2 penetrating through the dielectric layer 110 and the barrier layer 108 and disposed on the nitride channel layer 106 to be in contact with the 2DEG, the channel layer 116a disposed on the dielectric layer 110, the dielectric layer 114a disposed between the channel layer 116a and the dielectric layer 110, and the source S2 and the drain D2 disposed on the channel layer 116a, and the N-type transistor TR2 includes the gate G3 penetrating through the dielectric layer 110 and the barrier layer 108 and disposed on the nitride channel layer 106 to be in contact with the 2DEG, the channel layer 116b disposed on the dielectric layer 110, the dielectric layer 114b disposed between the channel layer 116b and the dielectric layer 110, and the source S3 and the drain D3 disposed on the channel layer 116b. The 2DEG is located below the gate G2, the source S2 and the drain D2 of the P-type transistor TR1 and below the gate G3, the source S3 and the drain D3 of the N-type transistor TR3.

In the semiconductor power device 70, the power transistor PT is a D-mode power transistor, the complementary logic circuit LC is electrically connected to the power transistor PT, and the channel layer of the P-type transistor TR1 and the channel layer of the N-type transistor TR2 in the complementary logic circuit LC are both the 2D material channel layers. Therefore, the complementary logic circuit LC may have low power dissipation and high-speed operating frequency, and the semiconductor power device 70 may have high electron mobility and high output current.

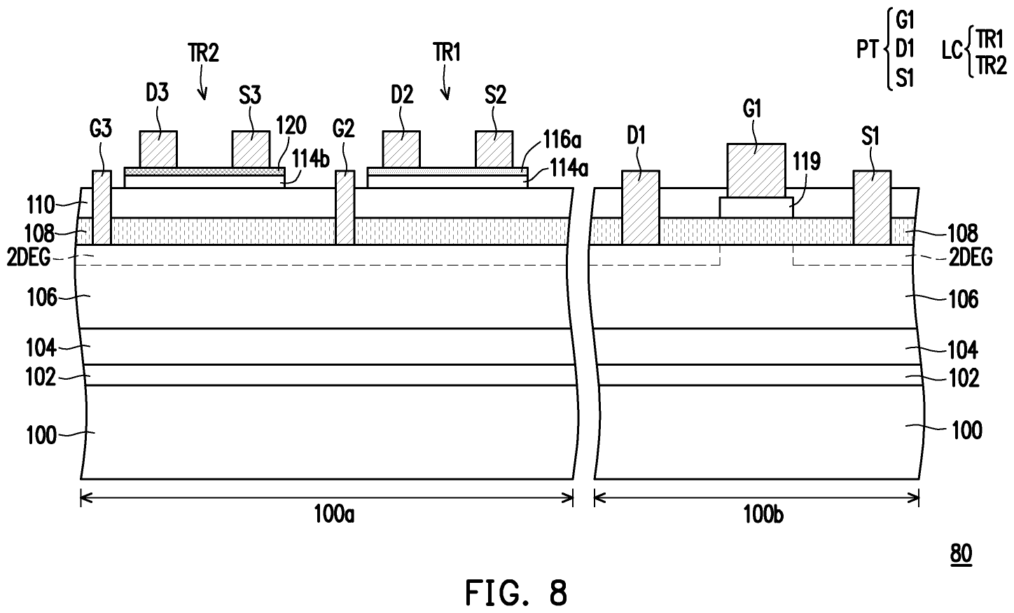

FIG. 8 is a schematic cross-sectional view of a semiconductor power device according to the eighth embodiments of the disclosure. In the present embodiment, elements that are the same as those in the seventh embodiment will be represented by the same reference symbols and will not be described again.

Referring to FIG. 8, the difference between the semiconductor power device 80 of the present embodiment and the semiconductor power device 70 is that in the semiconductor power device 80, the power transistor PT has the same configuration as the power transistor PT of the semiconductor power device 30.

In addition, in the present embodiment, since the power transistor PT is an E-mode power transistor, in the complementary logic circuit LC, the channel layer 116a of the P-type transistor TR1 is the 2D material channel layer, and the channel layer of the N-type transistor TR2 is the channel layer 120, which is not the 2D material channel layer.

In the semiconductor power device 80, the power transistor PT is a E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 80 may have high electron mobility and high output current.

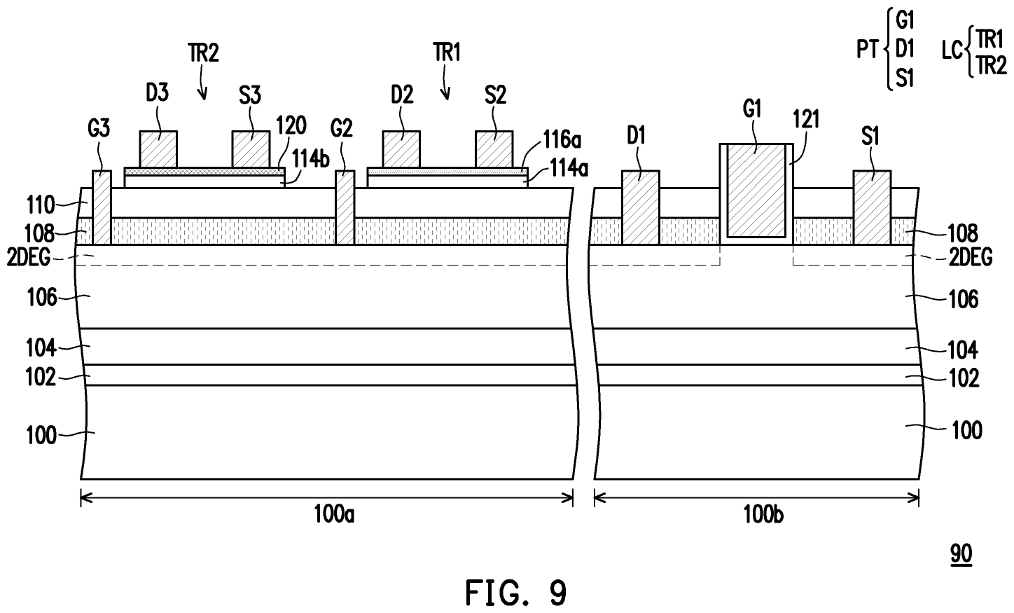

FIG. 9 is a schematic cross-sectional view of a semiconductor power device according to the ninth embodiment of the disclosure. In the present embodiment, elements that are the same as those in the eighth embodiment will be represented by the same reference symbols and will not be described again.

Referring to FIG. 9, the difference between the semiconductor power device 90 of the present embodiment and the semiconductor power device 80 is that in the semiconductor power device 90, the power transistor PT has the same configuration as the power transistor PT of the semiconductor power device 40.

In the semiconductor power device 90, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 90 may have high electron mobility and high output current.

In each of the above embodiments, the 2DEG is located in the nitride channel layer 106 and adjacent to the interface between the nitride channel layer 106 and the barrier layer 108, but the disclosure is not limited thereto. In other embodiments, the 2DEG may be located in an undoped buffer layer, which is explained below.

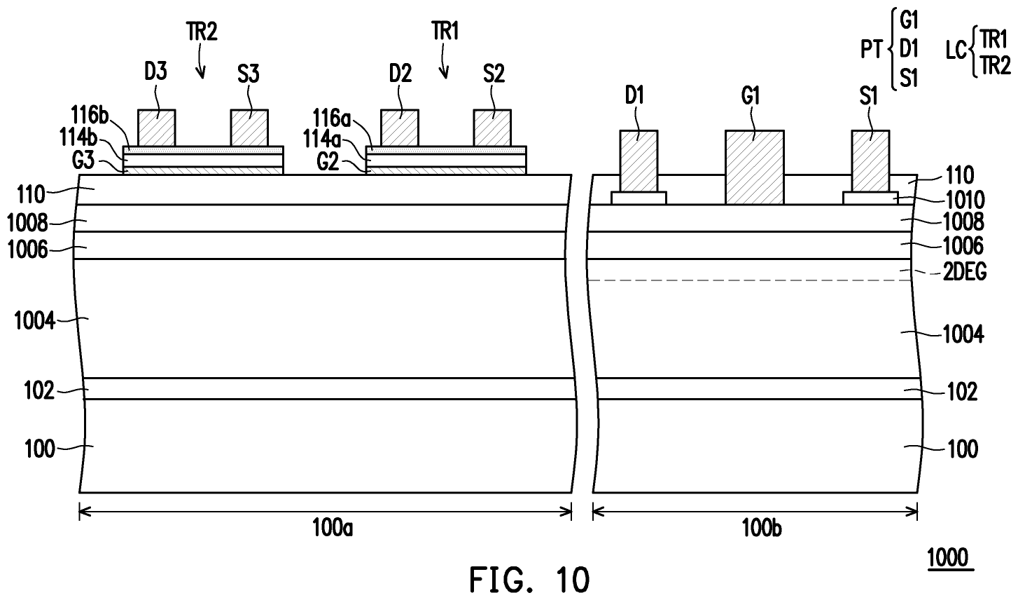

FIG. 10 is a schematic cross-sectional view of the semiconductor power device according to the tenth embodiment of the disclosure.

Referring to FIG. 10, the semiconductor power device 1000 includes the substrate 100, the nucleation layer 102, the undoped buffer layer 1004, the undoped spacer layer 1006, the doped AlGaAs layer 1008, the power transistor PT and the complementary logic circuit LC.

The nucleation layer 102 is disposed on the substrate 100. The undoped buffer layer 1004 is disposed on the nucleation layer 102. In the present embodiment, the undoped buffer layer 1004 is an undoped GaAs layer. The thickness of the undoped buffer layer 1004 is, for example, between 0.3 μm and 2 μm. The undoped spacer layer 1006 is disposed on the undoped buffer layer 1004. In the present embodiment, the undoped spacer layer 1006 is an undoped AlGaAs layer. The thickness of the undoped spacer layer 1006 is, for example, between 0.3 μm and 0.8 μm. The doped AlGaAs layer 1008 is disposed on the undoped spacer layer 1006. The thickness of the doped AlGaAs layer 1008 is, for example, between 5 nm and 20 nm. The doped AlGaAs layer 1008 may be used to improve the electron mobility. In other embodiments, the doped AlGaAs layer 1008 may be omitted depending on actual needs. The dielectric layer 110 is disposed on the doped AlGaAs layer 1008 as a passivation layer.

In addition, in the present embodiment, the 2DEG is only located in the power device region 100b, and is located in the undoped buffer layer 1004 and adjacent to the interface between the undoped buffer layer 1004 and the undoped spacer layer 1006.

The complementary logic circuit LC is disposed on the substrate 100 in the circuit region 100a, and may have the same configuration as the complementary logic circuit LC of the semiconductor power device 10.

The power transistor PT is disposed on the substrate 100 in the power device region 100b. In the present embodiment, the gate G1, the source S1 and the drain D1 of the power transistor PT penetrate through the dielectric layer 110 and disposed on the doped AlGaAs layer 1008. In addition, the doped GaAs layer 1010 is disposed between the source S1 and the doped AlGaAs layer 1008 and between the drain D1 and the doped AlGaAs layer 1008. Depending on actual needs, the gate G1 may be extended downward into the AlGaAs layer 1008 to modulate the threshold voltage.

In addition, in the present embodiment, the 2DEG is located below the gate G1, the source S1 and the drain S1. That is, the power transistor PT is a D-mode power transistor.

In the semiconductor power device 1000, the power transistor PT is a D-mode power transistor, the complementary logic circuit LC is electrically connected to the power transistor PT, and the channel layer of the P-type transistor TR1 and the channel layer of the N-type transistor TR2 in the complementary logic circuit LC are both the 2D material channel layers. Therefore, the complementary logic circuit LC may have low power dissipation and high-speed operating frequency, and the semiconductor power device 1000 may have high electron mobility and high output current.

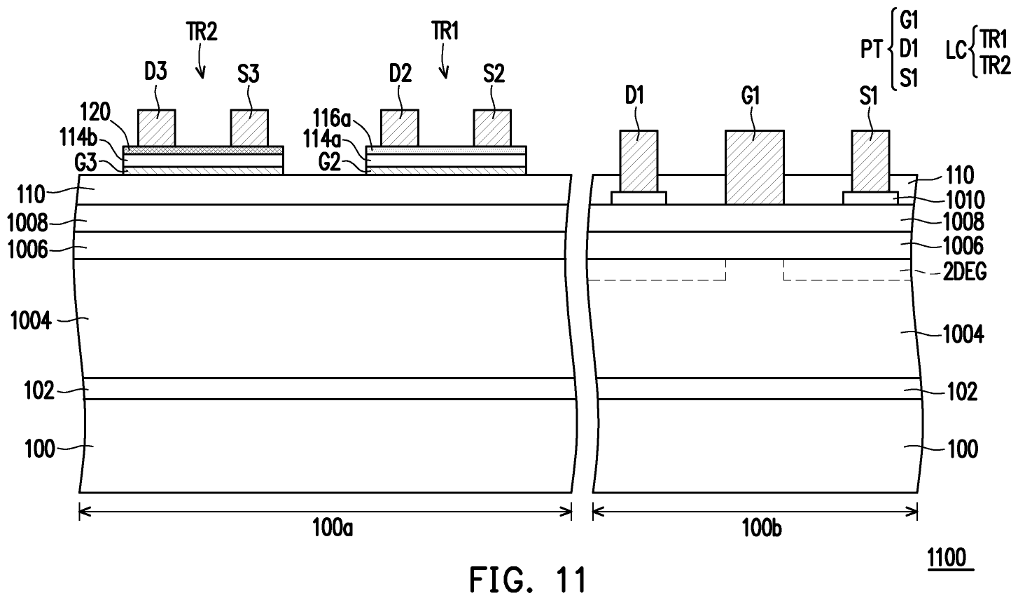

FIG. 11 is a schematic cross-sectional view of the semiconductor power device according to the eleventh embodiment of the disclosure. In the present embodiment, elements that are the same as those in the tenth embodiment will be represented by the same reference symbols and will not be described again.

Referring to FIG. 11, the difference between the semiconductor power device 1100 of the present embodiment and the semiconductor power device 1000 is that in the semiconductor power device 1100, there is no 2DEG below the gate G1 of the power transistor PT. That is, the power transistor PT is an E-mode power transistor.

In addition, in the present embodiment, since the power transistor PT is an E-mode power transistor, in the complementary logic circuit LC, the channel layer 116a of the P-type transistor TR1 is the 2D material channel layer, and the channel layer of the N-type transistor TR2 is the channel layer 120, which is not the 2D material channel layer.

In the semiconductor power device 1100, the power transistor PT is an E-mode power transistor, the complementary logic circuit LC is electrically connected to the power transistor PT, and the channel layer of the P-type transistor TR1 in the complementary logic circuit LC is the 2D material channel layer. Therefore, the complementary logic circuit LC may have low power dissipation and high-speed operating frequency, and the semiconductor power device 1100 may have high electron mobility and high output current.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor power device, comprising:
a substrate, having a circuit region and a power device region;
a buffer layer, disposed on the substrate;
a nitride channel layer, disposed on the buffer layer;
a barrier layer, disposed on the nitride channel layer;
a power transistor, disposed on the substrate in the power device region; and
a complementary logic circuit, disposed on the substrate in the circuit region and electrically connected to the power transistor, and comprising:
a P-type transistor, comprising a two-dimensional (2D) material channel layer; and
an N-type transistor, electrically connected to the P-type transistor,
wherein a two-dimensional electron gas (2DEG) is located in the nitride channel layer and adjacent to an interface between the nitride channel layer and the barrier layer.

2. The semiconductor power device of claim 1, wherein the 2DEG is located only in the power device region.

3. The semiconductor power device of claim 2, wherein the 2DEG is located below a gate, a source and a drain of the power transistor.

4. The semiconductor power device of claim 3, wherein each of the P-type transistor and the N-type transistor comprises:
a gate, disposed on the barrier layer;
a dielectric layer, disposed between the gate and the barrier layer;
a channel layer, disposed on the gate;
a gate dielectric layer, disposed between the gate and the channel layer; and
a source and a drain, disposed on the channel layer,
wherein the channel layer is the 2D material channel layer.

5. The semiconductor power device of claim 3, wherein each of the P-type transistor and the N-type transistor comprises:
a channel layer, disposed on the barrier layer;
a dielectric layer, disposed between the channel layer and the barrier layer;
a gate, a source and a drain, disposed on the channel layer; and
a gate dielectric layer, disposed between the gate and the channel layer,
wherein the channel layer is the 2D material channel layer.

6. The semiconductor power device of claim 2, wherein the 2DEG is not located below a gate of the power transistor.

7. The semiconductor power device of claim 6, wherein each of the P-type transistor and the N-type transistor comprises:
a gate, disposed on the barrier layer;
a dielectric layer, disposed between the gate and the barrier layer;
a channel layer, disposed on the gate;
a gate dielectric layer, disposed between the gate and the channel layer; and
a source and a drain, disposed on the channel layer,
wherein the channel layer of the P-type transistor is the 2D material channel layer, and the channel layer of the N-type transistor is not the 2D material channel layer.

8. The semiconductor power device of claim 6, wherein each of the P-type transistor and the N-type transistor comprises:
a channel layer, disposed on the barrier layer;
a dielectric layer, disposed between the channel layer and the barrier layer;
a gate, a source and a drain, disposed on the channel layer; and
a gate dielectric layer, disposed between the gate and the channel layer,
wherein the channel layer of the P-type transistor is the 2D material channel layer, and the channel layer of the N-type transistor is not the 2D material channel layer.

9. The semiconductor power device of claim 1, wherein the 2DEG is located in the power device region and the circuit region.

10. The semiconductor power device of claim 9, wherein the 2DEG is located below a gate, a source and a drain of the power transistor.

11. The semiconductor power device of claim 10, wherein each of the P-type transistor and the N-type transistor comprises:
a gate, penetrating through the barrier layer and disposed on the nitride channel layer, and in contact with the 2DEG;
a channel layer, disposed on the barrier layer;
a dielectric layer, disposed between the channel layer and the barrier layer; and
a source and a drain, disposed on the channel layer,
wherein the channel layer is the 2D material channel layer, and the 2DEG is located below the gates, the sources and the drains of the P-type transistor and the N-type transistor.

12. The semiconductor power device of claim 9, wherein the 2DEG is not located below a gate of the power transistor.

13. The semiconductor power device of claim 12, wherein each of the P-type transistor and the N-type transistor comprises:
a gate, penetrating through the barrier layer and disposed on the nitride channel layer, and in contact with the 2DEG;
a channel layer, disposed on the barrier layer;
a dielectric layer, disposed between the channel layer and the barrier layer; and
a source and a drain, disposed on the channel layer,
wherein the channel layer of the P-type transistor is the 2D material channel layer, the channel layer of the N-type transistor is not the 2D material channel layer, and the 2DEG is located below the gates, the sources and the drains of the P-type transistor and the N-type transistor.

14. The semiconductor power device of claim 1, wherein a material of the 2D material channel layer comprises graphene, silicene, boron nitride nanosheet, transition metal dichalcogenide, phosphorene, metal oxide nanosheet or Group II-VI compound.

15. A semiconductor power device, comprising:
a substrate, having a circuit region and a power device region;
an undoped buffer layer, disposed on the substrate;
an undoped spacer layer, disposed on the undoped buffer layer;
a power transistor, disposed on the substrate in the power device region; and
a complementary logic circuit, disposed on the substrate in the circuit region and electrically connected to the power transistor, and comprising:
a P-type transistor, comprising a two-dimensional (2D) material channel layer; and
an N-type transistor, electrically connected to the P-type transistor,
wherein a two-dimensional electron gas (2DEG) is located in the undoped buffer layer in the power device region and adjacent to an interface between the undoped buffer layer and the undoped spacer layer.

16. The semiconductor power device of claim 15, wherein the 2DEG is located below a gate, a source and a drain of the power transistor.

17. The semiconductor power device of claim 16, wherein each of the P-type transistor and the N-type transistor comprises:
a gate, disposed on the undoped spacer layer;
a dielectric layer, disposed between the gate and the undoped spacer layer;
a channel layer, disposed on the gate;
a gate dielectric layer, disposed between the gate and the channel layer; and
a source and a drain, disposed on the channel layer,
wherein the channel layer is the 2D material channel layer.

18. The semiconductor power device of claim 15, wherein the 2DEG is not located below a gate of the power transistor.

19. The semiconductor power device of claim 18, wherein each of the P-type transistor and the N-type transistor comprises:
a gate, disposed on the undoped spacer layer;
a dielectric layer, disposed between the gate and the undoped spacer layer;
a channel layer, disposed on the gate;
a gate dielectric layer, disposed between the gate and the channel layer; and
a source and a drain, disposed on the channel layer,
wherein the channel layer of the P-type transistor is the 2D material channel layer, and the channel layer of the N-type transistor is not the 2D material channel layer.

20. The semiconductor power device of claim 15, wherein a material of the 2D material channel layer comprises graphene, silicene, boron nitride nanosheet, transition metal dichalcogenide, phosphorene, metal oxide nanosheet or Group II-VI compound.
